(19) United States
(12) Patent Application Publication
(10) Pub. No.: US 2021/0119022 A1
(43) Pub. Date: Apr. 22, 2021

(54) METHODS FOR FORMING ULTRA-SHALLOW JUNCTIONS HAVING IMPROVED ACTIVATION

(71) Applicant: APPLIED Materials, Inc., Santa Clara, CA (US)

(72) Inventors: Jae Young Lee, Bedford, MA (US); Johannes M. Van Meer, Middleton, MA (US); Naushad K. Variam, Marblehead, MA (US)

(73) Assignee: APPLIED Materials, Inc., Santa Clara, CA (US)

(21) Appl. No.: 16/660,089

(22) Filed: Oct. 22, 2019

(51) Int. Cl. H01L 29/66; H01L 29/78; H01L 29/08; H01L 29/167; H01L 29/45; H01L 21/225; H01L 21/265; H01L 21/324; H01L 21/285

(52) U.S. Cl. CPC H01L 29/66795; H01L 29/7851; H01L 29/0847; H01L 29/167; H01L 21/28518; H01L 21/2253; H01L 21/26513; H01L 21/324; H01L 29/45

(57) ABSTRACT

Methods for forming semiconductor devices herein may include providing a metal gate, an interlayer dielectric (ILD), and an etch stop layer over a plurality of fins, wherein the ILD is formed atop the etch stop layer, and wherein the plurality of fins includes a source/drain (S/D) epitaxial region. The method may further include removing the etch stop layer from atop the S/D epitaxial region, and performing, through an opening in the ILD, an ion implant and a dopant ion implant to the S/D epitaxial region. In some embodiments, the method may further include thermally treating the semiconductor device to activate ions of the ion implant or ions of the dopant ion implant in the S/D epitaxial region to form an ultra-shallow junction.

### FIELD OF THE DISCLOSURE

The present disclosure relates to semiconductor devices, and more particularly, to methods for forming ultra-shallow junctions having improved activation.

### BACKGROUND OF THE DISCLOSURE

Integrated circuits (ICs) having a plurality of semiconductor devices including field effect transistors (FETs) are commonly used. Conventionally, the various regions of FETs (e.g., source/drain and source/drain extensions) are formed by introducing dopant atoms into a semiconductor substrate using methods such as ion implantation, etc. After the dopants have been introduced, the dopants are electrically activated by subjecting the semiconductor substrate to one or more annealing processes, such as low temperature thermal annealing, rapid thermal annealing, spike annealing, flash annealing or laser annealing.

Dopants, however, have a tendency to diffuse or expand both laterally and vertically away from the profile during annealing thereby increasing the dimensions of the various device regions. This diffusion of dopants is undesirable particularly as semiconductor devices are scaled down in size. Scaling device dimensions down to the molecular regime thus presents a fundamental and technological challenge for fabricating well defined structures with controlled atomic composition.

Furthermore, it is challenging to achieve higher dopant activation during contact engineering without compromising junction abruptness. Thus, there is a need to provide or fabricate ultra-shallow junctions within increased dopant activation to reduce contact reduction.

### SUMMARY OF THE DISCLOSURE

In some approaches, a method of forming a semiconductor device may include providing a metal gate, an interlayer dielectric (ILD), and an etch stop layer over a plurality of fins, wherein the ILD is formed atop the etch stop layer, and wherein the plurality of fins includes a source/drain (S/D) epitaxial region. The method may further include removing the etch stop layer from atop the S/D epitaxial region, and performing, through an opening in the ILD, an ion implant and a dopant ion implant to the S/D epitaxial region.

In some approaches, a method may include forming an ultra-shallow junction in a semiconductor device may include providing a metal gate, an interlayer dielectric (ILD), and an etch stop layer over a plurality of fins, wherein the ILD is formed atop the etch stop layer, and wherein the plurality of fins includes a source/drain (S/D) epitaxial region. The method may further include removing the etch stop layer from atop the S/D epitaxial region, and performing, through an opening in the ILD, an ion implant and then a dopant ion implant to the S/D epitaxial region.

In some approaches, a method of forming a semiconductor device may include providing a plurality of fins including a source/drain (S/D) epitaxial region, and providing an interlayer dielectric (ILD) atop an etch stop layer, the etch stop layer formed over the S/D epitaxial region. The method may further include removing the etch stop layer from atop the S/D epitaxial region, and performing, through an opening in the ILD, an ion implant and a dopant ion implant to the S/D epitaxial region, wherein the ion implant and the dopant ion implant are performed prior or after removal of the etch stop layer from atop the S/D epitaxial region.

### BRIEF DESCRIPTION OF THE DRAWINGS

FIG. 1 depicts a perspective view of a semiconductor device in accordance with embodiments of the present disclosure.

FIG. 2 depicts a perspective view of a semiconductor device in accordance with embodiments of the present disclosure.

FIG. 3 depicts a perspective view of a semiconductor device in accordance with embodiments of the present disclosure.

FIG. 4 is a process flow in accordance with embodiments of the present disclosure.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods and devices in accordance with the present disclosure will now be described more fully hereinafter with reference to the accompanying drawings, where embodiments of the methods are shown. The methods and devices may be embodied in many different forms and are not to be construed as being limited to the embodiments set forth herein. Instead, these embodiments are provided so the disclosure will be thorough and complete, and will fully convey the scope of methods and devices to those skilled in the art.

Embodiments herein are directed to methods for forming ultra-shallow junctions with high dopant activation through vacancy engineering. By manipulating vacancy concentration, size, and location, ultra-shallow junctions with increased dopant activation can be achieved to reduce contact resistance. As will be described in greater detail herein, embodiments of the present disclosure manipulate the vacancy concentration above an equilibrium concentration, thereby reducing dopant (e.g., boron) interstitial clustering. By doing so, upon annealing, the diffusion of dopant is suppressed to the point that the as-implanted dopant distribution is similar to the distribution following annealing.

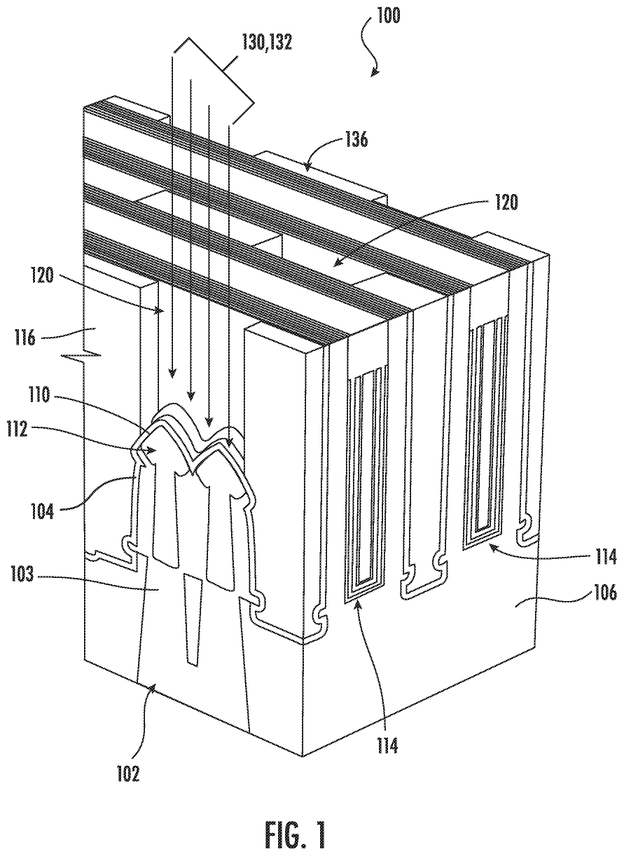

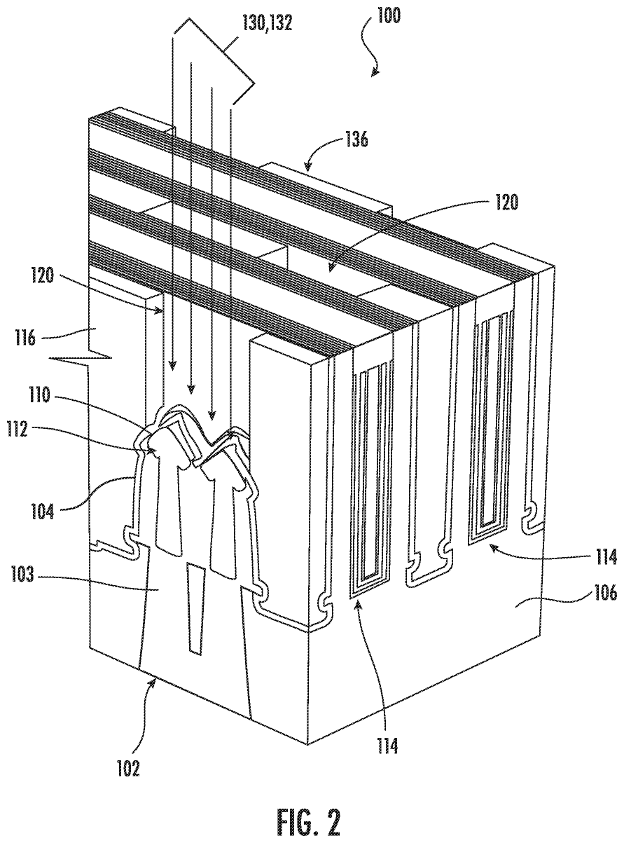

Turning now to FIGS. 1-2, there is shown cross-sectional views of a FinFET semiconductor device (hereinafter “device”) 100 according to embodiments of the disclosure. The device 100 may include a finned substrate (hereinafter “substrate”) 102 including a plurality of fins 103, and an etch stop layer 104 atop a STI layer 106. In some non-limiting embodiments, the etch stop layer 104 may be silicon oxide or a silicon nitride deposited directly atop a surface 110 of a source/drain (S/D) epitaxial region 112 of the fins 103.

The term “substrate” and/or “finned substrate” as used herein are intended to include a semiconductor substrate, a semiconductor epitaxial layer deposited or otherwise formed on a semiconductor substrate and/or any other type of semiconductor body. All such structures are contemplated as falling within the scope of the present embodiments. For example, the semiconductor substrate may comprise a semiconductor wafer (e.g., silicon, SiGe, or an SOI wafer) or one or more die on a wafer, and any epitaxial layers or other type semiconductor layers formed there over or associated therewith. A portion or entire semiconductor substrate may be amorphous, polycrystalline, or single-crystalline. In addition to the aforementioned types of substrates, the semiconductor substrate employed in the present embodiments may also comprise a hybrid oriented (HOT) semiconductor substrate having surface regions of different crystallographic orientation. The semiconductor substrate may be doped, undoped, or contain doped regions and undoped regions therein. The semiconductor substrate may contain regions with strain and regions without strain therein, or contain regions of tensile strain and compressive strain.

In various embodiments, the plurality of fins 103 of the substrate 102 may be fabricated using any suitable process including one or more photolithography and etch processes. The photolithography process for forming the plurality of fins 103 may include forming a photoresist layer (not shown) overlying the substrate 102 (e.g., on a silicon layer), exposing the resist to a pattern, performing post-exposure bake processes, and developing the resist to form a masking element including the resist. The masking element may then be used to etch the plurality of fins 103 into the silicon layer, e.g., using reactive ion etch (RIE) and/or other suitable processes. In one embodiment, the plurality of fins 103 are formed using a sidewall image transfer technique. In another embodiment, the plurality of fins 103 are formed by a double-patterning lithography (DPL) process. DPL is a method of constructing a pattern on a substrate by dividing the pattern into two interleaved patterns. DPL allows enhanced feature (e.g., fin) density. Various DPL methodologies may be used including, but not limited to, double exposure (e.g., using two mask sets), forming spacers adjacent features and removing the features to provide a pattern of spacers, resist freezing, and/or other suitable processes.

As further shown, the device 100 may include one or more metal gates 114 formed in an interlayer dielectric (ILD) 116. Although not shown for the sake of brevity, a replacement metal gate (RMG) process may be conducted to form the metal gates 114. A plurality of contact hole openings 120 may then be formed through the ILD 116, adjacent the metal gates 114. In some embodiments, a contact hole formation process may remove the ILD 116 selective to the etch stop layer 104.

As shown in FIG. 1, an ion implant 130 and a dopant ion implant 132 may be then performed through the contact hole openings 120 to impact the S/D epitaxial region 112. In this embodiment, the ion implant 130 and the dopant ion implant 132 are performed with the etch stop layer 104 intact within the contact hole openings 120. In the embodiment of FIG. 2, the ion implant 130 and the dopant ion implant 132 may be performed after the etch stop layer 104 is removed from atop the S/D epitaxial region 112 within the contact hole openings 120, for example, via a reactive ion etch (RIE). In yet other embodiments, the ion implant 130 may be performed through the etch stop layer 104, while the dopant ion implant 132 is delivered to the S/D epitaxial region 112 after the etch stop layer 104 is removed.

In various embodiments, the ion implant 130 may be a helium ion implant performed at a low energy, e.g., between approximately 0.5 keV and a few keV. The ion implant 130 may be delivered at a dose of E15 to E16, and with a uniform or controlled dose rate. Although non-limiting, the ion implant 130 may be performed at a room temperature (e.g., approximately 20 to 25 degrees Celsius), or at an elevated temperature (e.g., 150 degrees Celsius). The ion implant 130 may be delivered vertically or at a non-zero angle with respect to a perpendicular to a plane defined by a top surface 136 of the device 100.

Following the ion implant 130, the S/D epitaxial region 112 of the plurality of fins 103 may be doped via the dopant ion implant 132 with, e.g., boron or phosphorous. In other embodiments, the dopant ion implant 132 may include aluminum, gallium, indium, thallium, nitrogen, phosphorous, arsenic, antimony, and bismuth. In some embodiments, the dopant ion implant 132 is performed at room temperature. It will be appreciated that combining a low-energy He ion implant 130 helps create stable vacancies and clusters of vacancies to reduce B or phosphorous diffusion that may occur as a result of the dopant ion implant 132. Advantageously, the low-energy He ion implant 130 will create mostly small vacancy clusters, which may be further controlled by adjusting both a distance between the ion implant 130 and the surface 110 of a source/drain (S/D) epitaxial region 112 of the fins 103, and a temperature of the ion implant 130. Creating an increased number of vacancy concentrations in close proximity to boron or phosphorous projected range, i.e., the average depth of the implanted ions, helps boost activation.

In some embodiments, the implant energy of the ion implant 130 and or the dopant ion implant 132 ranges from 0.5 keV to 1 keV for the embodiment shown in FIG. 1, i.e., when the etch stop layer 104 has been removed prior to the ion implant 130 and the dopant ion implant 132. However, in the embodiment of FIG. 2, wherein the etch stop layer 104 remains in place during the ion implant 130 and the dopant ion implant 132, the energies of the ion implant 130 and the dopant ion implant 132 are increased so the ions may penetrate the etch stop layer 104 and impact the S/D epitaxial region 112. Although non-limiting, in the embodiment of FIG. 2, the implant energy of the ion implant 130 may be 1.0 keV-1.5 keV and the implant energy of the dopant ion implant 132 may be 1.5 keV-5 keV.

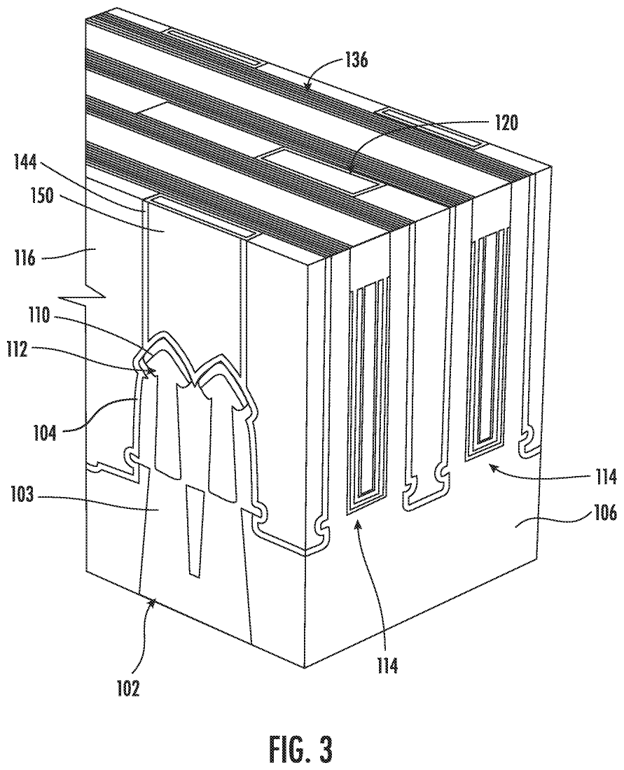

Turning now to FIG. 3, further formation of the device 100 according to embodiments of the present disclosure will be described. Following the dopant ion implant 132, the device 100 may be thermally treated (not shown) to activate ions imparted trough the ion implant 130 and/or the dopant ion implant 132 in the S/D epitaxial region 112 to form an ultra-shallow junction. Exemplary thermal treatments include, but are not limited to, low temperature thermal annealing, rapid thermal annealing, spike annealing, flash annealing or laser annealing.

The device 100 may then undergo a silicidation process to form a silicide or silicide layer 144 over the S/D epitaxial region 112. As shown, the silicide layer 144 may be formed along the exposed surfaces of the contact hole openings 120 and along the surface 110 of the S/D epitaxial region 112 of the fins 103. Following the silicidation process, the device 100 may receive a contact plug fill and CMP to form a set of contacts 150 within one or more of the contact hole openings 120.

Although non-limiting, formation of the set of contacts 150 may include depositing a conductive material into the contact hole openings, wherein the conductive material may include a variety of low-resistance metal materials, such as aluminum (Al), titanium (Ti), tantalum (Ta), tungsten (W), niobium (Nb), molybdenum (Mo), copper (Cu) or the like. The conductive material of the set of contacts 150 can form suitable Ohmic contact between the conductive material and the silicide layer 144 and/or between the conductive material and the S/D epitaxial region 112 underneath. Then, a planarization step, such as a chemical mechanical polish (CMP) process or an etching back process or combination thereof, can be performed so that the set of contacts 150 is planar with the top surface 136 of the device 100, thereby completing fabrication of the device.

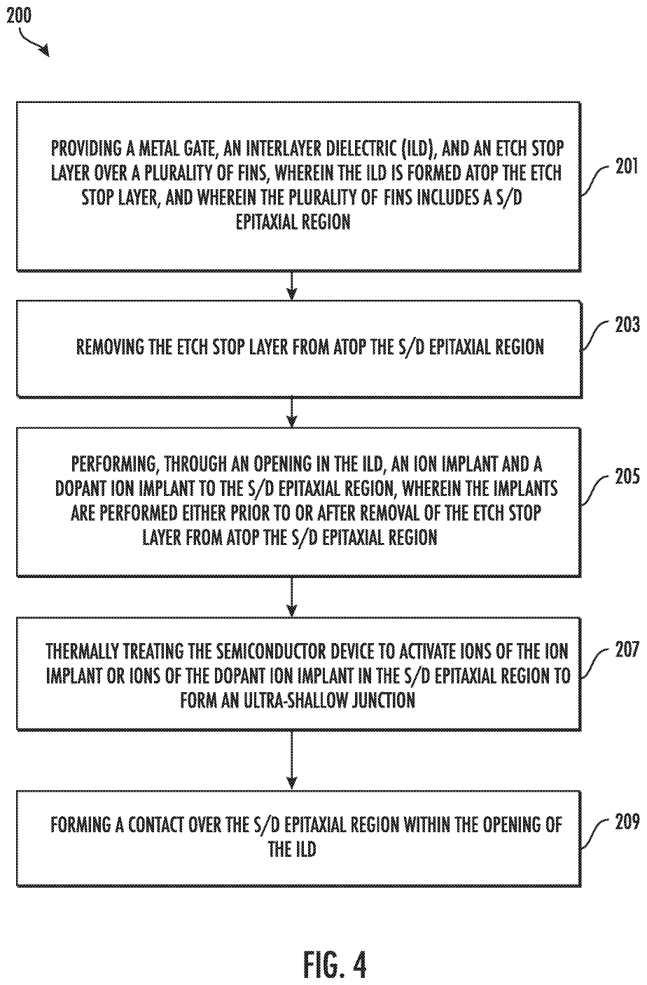

Turning now to FIG. 4, a method 200 for forming a semiconductor device according to embodiments of the present disclosure will be described in greater detail. At block 201, the method 200 may include providing a metal gate, an ILD, and an etch stop layer over a plurality of fins, wherein the ILD is formed atop the etch stop layer, and wherein the plurality of fins includes a S/D epitaxial region.

At block 203, the method 200 may include removing the etch stop layer from atop the S/D epitaxial region. In some embodiments, the etch stop layer may be removed via RIE.

At block 205, the method 200 may include performing, through an opening in the ILD, an ion implant and a dopant ion implant to the S/D epitaxial region, wherein the ion implant and the dopant ion implant are performed either prior to or after removal of the etch stop layer from atop the S/D epitaxial region. In some embodiments, the ion implant may be a helium ion implant having an implant energy between 0.5 keV and 1 keV. In some embodiments, the dopant ion implant may be a boron or phosphor implant.

At block 207, the method 200 may include thermally treating the semiconductor device to activate ions of the ion implant or ions of the dopant ion implant in the S/D epitaxial region to form an ultra-shallow junction.

At block 209, the method 200 may optionally include forming a contact over the S/D epitaxial region within the opening of the ILD. In some embodiments, the contact may be a conductive material deposited over a silicide formed atop the S/D epitaxial region.

In view of the foregoing, at least the following advantages are achieved by the embodiments disclosed herein. Firstly, stable vacancies and clusters of vacancies formed by low energy He implant act in reducing B diffusion. This is because low energy He implants create mostly small clusters. The proximity to surface and implant temperature also plays a role in determining the vacancy cluster size. Secondly, placement of significant vacancies concentrations in close proximity to boron projected range helps boost activation. This is due to local suppression of supersaturation of interstitials due to trapping Is by vacancy clusters. Thirdly, optimizing implant conditions and subsequent anneal processes will help form shallow junction with improved activation.

In various embodiments, design tools can be provided and configured to create the datasets used to pattern the semiconductor layers as described herein. For example, data sets can be created to generate photomasks used during lithography operations to pattern the layers for structures as described herein. Such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance running software, or implemented in hardware.

As used herein, a module might be implemented utilizing any form of hardware, software, or a combination thereof. For example, one or more processors, controllers, ASICs, PLAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Although various features or elements of functionality may be individually described or claimed as separate modules, one of ordinary skill in the art will understand these features and functionality can be shared among one or more common software and hardware elements.

As used herein, the term “depositing” may include any now known or later developed techniques appropriate for the material to be deposited. For example, depositing may include: chemical vapor deposition (CVD), low-pressure CVD (LPCVD), plasma-enhanced CVD (PECVD), semi-atmosphere CVD (SACVD) and high density plasma CVD (HDPCVD). Depositing may further include: rapid thermal CVD (RTCVD), ultra-high vacuum CVD (UHVCVD), limited reaction processing CVD (LRPCVD), metal-organic CVD (MOCVD), sputtering deposition, and ion beam deposition. Depositing may further include: electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, and evaporation.

For the sake of convenience and clarity, terms such as “top,” “bottom,” “upper,” “lower,” “vertical,” “horizontal,” “lateral,” and “longitudinal” are used herein to describe the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporating the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method of forming a semiconductor device, comprising:
providing a metal gate, an interlayer dielectric (ILD), and an etch stop layer over a plurality of fins, wherein the ILD is formed atop the etch stop layer, and wherein the plurality of fins includes a source/drain (S/D) epitaxial region;
removing the etch stop layer from atop the S/D epitaxial region;
performing, through an opening in the ILD, an ion implant and a dopant ion implant to the S/D epitaxial region.

2. The method of claim 1, wherein the ion implant and the dopant ion implant are performed prior to removal of the etch stop layer from atop the S/D epitaxial region.

3. The method of claim 1, wherein the ion implant and the dopant ion implant are performed after removal of the etch stop layer from atop the S/D epitaxial region.

4. The method of claim 1, further comprising thermally treating the semiconductor device to activate ions of the ion implant or ions of the dopant ion implant in the S/D epitaxial region to form an ultra-shallow junction.

5. The method of claim 1, further comprising forming a contact over the S/D epitaxial region.

6. The method of claim 5, further comprising forming a silicide atop the S/D epitaxial region, wherein the contact is formed over the silicide.

7. The method of claim 1, wherein the ion implant is a helium ion implant having an implant energy between 0.5 keV and 1 keV, wherein the dopant ion implant is a boron or phosphor ion implant.

8. A method of forming an ultra-shallow junction in a semiconductor device, the method comprising:
providing a metal gate, an interlayer dielectric (ILD), and an etch stop layer over a plurality of fins, wherein the ILD is formed atop the etch stop layer, and wherein the plurality of fins includes a source/drain (S/D) epitaxial region;
removing the etch stop layer from atop the S/D epitaxial region;
performing, through an opening in the ILD, an ion implant and then a dopant ion implant to the S/D epitaxial region.

9. The method of claim 8, wherein the ion implant and the dopant ion implant are performed prior to or after removal of the etch stop layer from atop the S/D epitaxial region.

10. The method of claim 8, further comprising thermally treating the semiconductor device to activate ions of the ion implant or ions of the dopant ion implant in the S/D epitaxial region to form the ultra-shallow junction.

11. The method of claim 8, further comprising forming a contact over the S/D epitaxial region.

12. The method of claim 11, further comprising forming a silicide atop the S/D epitaxial region, wherein the contact is formed over the silicide.

13. The method of claim 8, wherein the ion implant is a helium ion implant, and wherein the dopant ion implant is a boron or ion phosphor implant.

14. A method of forming a semiconductor device, the method comprising:
providing a plurality of fins including a source/drain (S/D) epitaxial region;
providing an interlayer dielectric (ILD) atop an etch stop layer, the etch stop layer formed over the S/D epitaxial region;
removing the etch stop layer from atop the S/D epitaxial region;
performing, through an opening in the ILD, an ion implant and a dopant ion implant to the S/D epitaxial region, wherein the ion implant and the dopant ion implant are performed prior or after removal of the etch stop layer from atop the S/D epitaxial region.

15. The method of claim 14, further comprising forming a contact over the S/D epitaxial region.

16. The method of claim 15, further comprising forming a silicide atop the S/D epitaxial region, wherein the contact is formed over the silicide.

17. The method of claim 16, further comprising forming the silicide along a set of sidewalls of the opening in the ILD.

18. The method of claim 14, further comprising thermally treating the semiconductor device to activate ions of the ion implant or ions of the dopant ion implant in the S/D epitaxial region to form the ultra-shallow junction.

19. The method of claim 18, wherein the thermally treating the semiconductor device comprises performing a rapid thermal anneal.

20. The method of claim 14, wherein the ion implant is a helium ion implant, and wherein the dopant ion implant is a boron or phosphor ion implant.
